(19) United States
(12) Patent Application Publication
(10) Pub. No.: US 2026/0321549 A1
(43) Pub. Date: Oct. 15, 2026

(54) FILM FORMING METHOD, PLASMA PRCESSING METHOD, AND PLASMA PRCESSING APPARATUS

(71) Applicant: Tokyo Electron Limited, Tokyo (JP)

(72) Inventors: Sho KUBO, Miyagi (JP); Takehito WATANABE, Miyagi (JP); Shinya MORIKITA, Miyagi (JP)

(73) Assignee: Tokyo Electron Limited, Tokyo (JP)

(21) Appl. No.: 19/696,703

(22) Filed: Jun. 3, 2026

Related U.S. Application Data
(63) Continuation of application No. PCT/JP2024/042992, filed on Dec. 5, 2024.

(30) Foreign Application Priority Data
Dec. 14, 2023 (JP) 2023-211068

(51) Int. Cl. H01J 37/32

(52) U.S. Cl. CPC H01J 37/32449; H01J 37/32651; H01J 37/32697; H01J 37/32816; H01J 2237/332

(57) ABSTRACT

The disclosed film forming method uses a plasma processing apparatus. The film forming method includes: supplying a carbon-containing gas into a plasma processing space inside the chamber; generating plasma from the gas in the plasma processing space to form a film on a portion exposed to the plasma processing space during execution of the supplying a carbon-containing gas, at least a part of the portion including a conductor; and supplying at least one bias signal to the portion during a period in which the generating plasma is being performed.

### CROSS-REFERENCE TO RELATED APPLICATIONS

This application is a Continuation of PCT International Application No PCT/JP2024/042992, filed on Dec. 5, 2024, which claims priority under 35 U.S.C. § 119(a) to Japanese Patent Application No. 2023-211068, filed in Japan on Dec. 14, 2023 all of which are hereby expressly incorporated by reference into the present application.

### BACKGROUND

### Field

Example embodiments of the disclosure relate to a film forming method, a plasma processing method, and a plasma processing apparatus.

### Description of the Related Art

A plasma processing system is used in plasma processing of substrates. Japanese Unexamined Patent Publication No. 2008-505490 discloses a method for optimizing resistance to etching of a substrate in a plasma processing system. The method includes flowing a precoat gas mixture into a plasma processing chamber and irradiating with a first plasma of the precoat gas mixture.

### SUMMARY

In one exemplary embodiment, a film forming method using a plasma processing apparatus is provided. The plasma processing apparatus includes a chamber, a substrate support, an upper electrode, a first insulator, and a shield. The chamber is electrically grounded and provides a plasma processing space. The substrate support is in the chamber and is configured to support a substrate. The upper electrode is a part of a ceiling configured to close an opening of the chamber above the plasma processing space, is configured to apply radio frequency power for generating a plasma, and is above the substrate support. The first insulator is a part of the ceiling and is between the upper electrode and the chamber to electrically isolate the upper electrode from the chamber. The shield is another part of the ceiling, has conductivity, is formed from a silicon-containing material, and extends from a peripheral edge of the upper electrode to the chamber. The film forming method includes: supplying a carbon-containing gas into a plasma processing space inside the chamber; generating plasma from the gas in the plasma processing space to form a film on a portion exposed to the plasma processing space during execution of the supplying a carbon-containing gas, at least a part of the portion including a conductor; and supplying at least one bias signal to the portion during a period in which the generating plasma is being performed.

### BRIEF DESCRIPTION OF DRAWINGS

FIG. 1 is a diagram for explaining an example configuration of a plasma processing system.

FIG. 2 is a diagram for explaining an example configuration of a capacitively coupled plasma processing apparatus.

FIG. 3 is a diagram for explaining a plasma processing apparatus according to one exemplary embodiment.

FIG. 4 is a flowchart for explaining a plasma processing method and a film forming method according to one exemplary embodiment.

FIG. 5 is a diagram for explaining a plasma processing apparatus according to another exemplary embodiment.

### DETAILED DESCRIPTION

Various exemplary embodiments will now be described in detail with reference to the drawings. In the drawings, like reference numerals denote like or corresponding components.

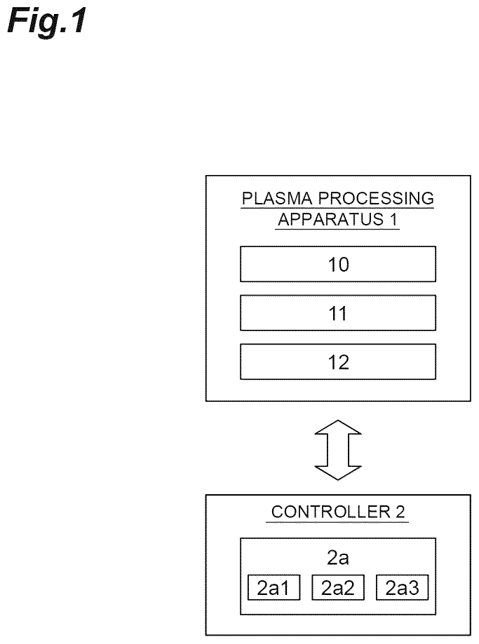

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in the plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, an AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads to execute the program from the storage 2a2. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

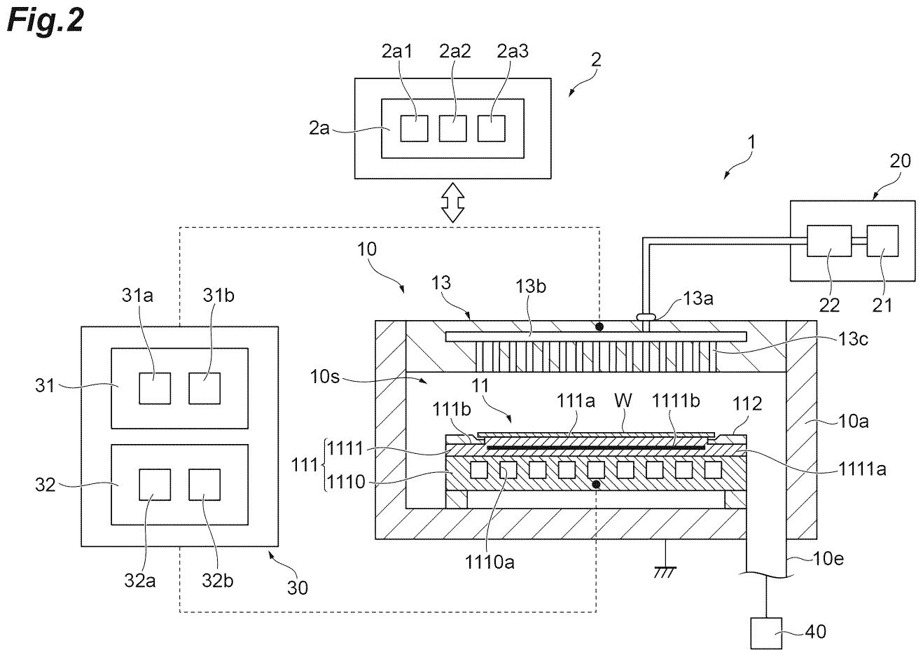

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in the plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulating member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to at least one of an RF source 31 or a DC source 32 described below may be disposed in the ceramic member 1111a. In this case, the at least one RF/DC electrode functions as the lower electrode. If at least one of a bias RF signal or a DC signal described below are supplied to the at least one RF/DC electrode, the RF/DC electrode is also called a bias electrode. It is noted that the conductive member of the base 1110 and the at least one RF/DC electrode may each function as a lower electrode. The electrostatic electrode 1111b may also function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, and one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include at least one flow modulation device that can modulate or pulse the flow of the at least one process gas.

The electric power source 30 includes an RF source 31 coupled to the plasma processing chamber 10 through at least one impedance matching circuit. The RF source 31 is configured to supply at least one RF signal (RF power) to at least one of at least one lower electrode or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to at least one of the at least one lower electrode or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to at least one of the at least one lower electrode or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to at least one of the at least one lower electrode or the at least one upper electrode. The voltage pulses may have a rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby function as a voltage pulse generator. In the case that the second DC generator 32b and the waveform generator function as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

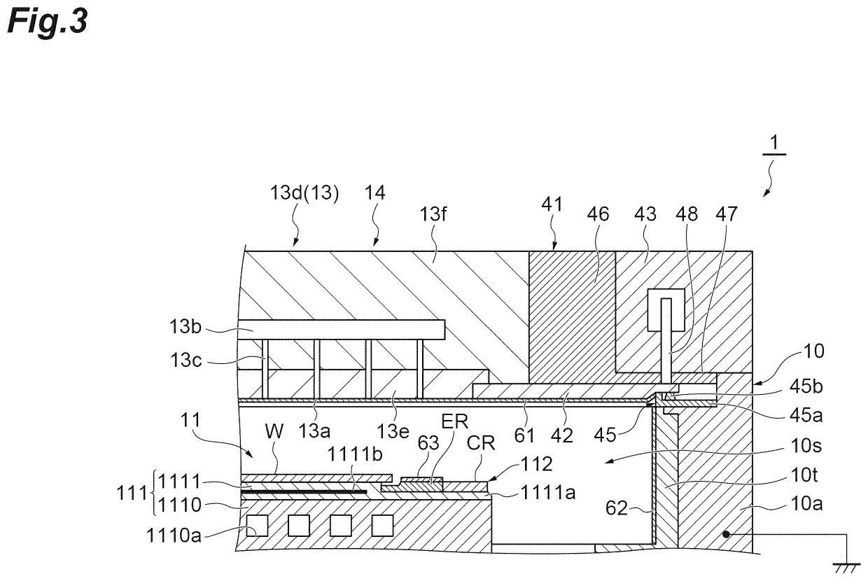

A plasma processing apparatus according to one exemplary embodiment will now be described with reference to FIGS. 2 and 3. FIG. 3 is a diagram showing an upper electrode and a shield provided in the plasma processing apparatus shown in FIG. 2.

As shown in FIG. 3, the sidewall 10a of the plasma processing chamber 10 has a substantially cylindrical shape. The sidewall 10a is connected to the ground, and its potential is set to the ground potential. The upper end of the sidewall 10a is open.

The plasma processing apparatus 1 has a ceiling 14 above the plasma processing space 10s. The ceiling 14 is provided so as to close the opening of the plasma processing chamber 10. That is, the ceiling 14 covers and closes the opening at the upper end of the sidewall 10a. A part of the ceiling 14 is exposed to the plasma processing space 10s.

The showerhead 13 constituting a part of the ceiling 14 includes at least one upper electrode 13d. The upper electrode 13d is a part of the ceiling 14, is configured to be capable of applying radio frequency power, and is provided above the substrate support 11. The upper electrode 13d is electrically connected to, for example, the first RF generator 31a. The first RF generator 31a is an example of a radio frequency power supply.

The upper electrode 13d includes a ceiling plate 13e and a first support 13f. The ceiling plate 13e has a substantially disk shape. The ceiling plate 13e is in contact with the plasma processing space 10s. The ceiling plate 13e includes a conductive material such as silicon. The ceiling plate 13e may be formed from, for example, a conductive material such as silicon. The ceiling plate 13e may be configured by forming an anticorrosive film on the surface of a conductive member such as aluminum. The anticorrosive film is formed from, for example, a material such as aluminum oxide or yttrium oxide.

The first support 13f is provided on the ceiling plate 13e. The first support 13f supports the ceiling plate 13e in a detachable manner. The first support 13f is formed from, for example, aluminum. The first support 13f provides at least one gas diffusing space 13b inside thereof. The first support 13f, together with the ceiling plate 13e, provides at least one gas feeding port 13c. The at least one gas feeding port 13c extends downward from the at least one gas diffusing space 13b and penetrates through the ceiling plate 13e.

The ceiling 14 further includes a first insulator 41. The first insulator 41 is an example of an insulating portion. The first insulator 41 is a part of the ceiling 14. The first insulator 41 is formed from an insulator such as quartz. The first insulator 41 includes a first insulating portion 46 and a second insulating portion 47. The first insulating portion 46 is provided between the upper electrode 13d and the plasma processing chamber 10. The first insulating portion 46 electrically isolates the upper electrode 13d from the plasma processing chamber 10. The first insulating portion 46 is provided on the outer side of the upper electrode 13d (on the sidewall 10a side). The first insulating portion 46 has a substantially annular shape and extends in the circumferential direction so as to surround the upper electrode 13d. The second insulating portion 47 will be described later.

The ceiling 14 further includes a shield 42. The shield 42 is another part of the ceiling 14 and has conductivity. The shield 42 includes, a silicon-containing material. The shield 42 may be formed from, for example, a silicon-containing material. The shield 42 extends from the peripheral edge of the upper electrode 13d to the plasma processing chamber 10. The shield 42 extends in the circumferential direction so as to surround the peripheral portion of the ceiling plate 13e. The shield 42 has, for example, a substantially annular shape. The shield 42 is provided, for example, below the first insulator 41. The shield 42 extends so that the first insulator 41 is not exposed to the plasma processing space 10s. In the example shown in FIG. 3, the shield 42 is provided below a part of the first support 13f, the first insulator 41, and a part of a second support 43 described later.

At least a part of a portion exposed to the plasma processing space 10s (hereinafter also referred to as an exposed portion) is composed of a conductor. The exposed portion includes, for example, at least a part of the ceiling 14, at least a part of the sidewall 10a, and at least a part of the substrate support 11. For example, the exposed portion of the ceiling 14 is composed of conductors including the upper electrode 13d and the shield 42. For example, the exposed portion of the ceiling 14 is composed of only conductors. In the example shown in FIG. 3, the exposed portion of the ceiling 14 is composed of only the upper electrode 13d (or the ceiling plate 13e) and the shield 42.

In the plasma processing apparatus 1, the entire region of the exposed portion of the ceiling 14 is formed from a conductor (conductive material). Therefore, it is possible to remove reaction products adhering to the exposed portion by supplying a bias signal during dry cleaning. As a result, it is possible to suppress the reaction products from adhering to the substrate W as particles.

The plasma processing chamber 10 may further include a second support 43. The second support 43 is provided on the outer side of the first insulator 41 and above the shield 42. A small gap is provided between the second support 43 and the shield 42. The second support 43 is provided on the sidewall 10a of the plasma processing chamber 10. The second support 43 is electrically connected to the sidewall 10a of the plasma processing chamber 10. The potential of the second support 43 is set to the ground potential. The first insulator 41 is provided between the first support 13f of the upper electrode 13d and the second support 43. The second support 43 has a substantially annular shape and extends in the circumferential direction so as to surround the first insulator 41. The second support 43 is formed from a metal such as aluminum.

The second insulating portion 47 is provided on the outer side of the first insulating portion 46 and on the shield 42. The second insulating portion 47 has, for example, a substantially annular shape and extends in the circumferential direction so as to surround the first insulating portion 46. The second insulating portion 47 extends so as to protrude outward from the lower end of the first insulating portion 46. The second insulating portion 47 is interposed between the plasma processing chamber 10 and the shield 42. In the example shown in FIG. 3, the second insulating portion 47 is provided such that its lower surface is in contact with the upper surface of the outer portion of the shield 42. The second insulating portion 47 is provided between the shield 42 and the second support 43.

In this manner, in the plasma processing apparatus 1, the first insulator 41 having the first insulating portion 46 and the second insulating portion 47 is interposed between the upper electrode 13d and the plasma processing chamber 10 and between the plasma processing chamber 10 and the shield 42.

The plasma processing apparatus 1 further includes at least one second insulator 45. The at least one second insulator 45 is provided below the shield 42. The at least one second insulator 45 is interposed between the plasma processing chamber 10 and the shield 42. The shield 42 is supported between the second insulating portion 47 and the at least one second insulator 45.

In the example shown in FIG. 3, the at least one second insulator 45 includes a third support 45a and a sealing member 45b. The third support 45a is provided on the sidewall 10a. The third support 45a supports the shield 42 from below. An inner part of the third support 45a may be exposed to the plasma processing space 10s below the ceiling 14. The sealing member 45b is provided between the shield 42 and the third support 45a. The sealing member 45b is disposed so as to be in contact with an outer portion of the shield 42 and an outer portion of the third support 45a. The sealing member 45b is, for example, an O-ring that separates a reduced pressure environment including the plasma processing space 10s from an atmospheric pressure environment.

At least one of the upper electrode 13d or the shield 42 is electrically connected to the second DC generator 32b. In the example shown in FIG. 3, a DC connector 48 is provided inside the second support 43. The DC connector 48 extends from the inside of the second support 43, through the second insulating portion 47, and is connected to an outer portion of the shield 42. The outer portion of the shield 42 is, for example, a radially outer portion of the shield 42 that is not exposed to the plasma processing space 10s. The outer portion of the shield 42 may be a peripheral portion of the shield 42. The outer portion of the shield 42 is supported while being sandwiched between the lower end of the DC connector 48 and the at least one second insulator 45. For example, the lower end of the DC connector 48 is provided immediately above the sealing member 45b of the at least one second insulator 45 in the circumferential direction.

A second DC signal generated by the second DC generator 32b is applied to at least one of the upper electrode 13d or the shield 42 through the DC connector 48. In the plasma processing apparatus 1, even when the DC connector 48 is located on the outer side of the first insulator 41, the DC connector 48 penetrates through the second insulating portion 47 and connects to the shield 42, so that the second DC signal can be appropriately applied to the shield 42. By applying the second DC signal to the shield 42, the second DC signal is applied to the upper electrode 13d through the shield 42. The second DC signal applied to at least one of the upper electrode 13d or the shield 42, that is, the bias signal, is a negative DC voltage or a voltage pulse (a pulse of negative voltage). The voltage pulse is periodically applied at a frequency of, for example, 400 kHz. The absolute value of the voltage level of the DC voltage or voltage pulse that is the second DC signal is 100 V or more. This causes a negative DC voltage having an absolute value of 100 V or more to be applied to at least one of the upper electrode 13d or the shield 42.

In the plasma processing apparatus 1, the first RF generator 31a may generate a signal having a frequency of, for example, 100 MHz as a source RF signal and supply the signal to the upper electrode 13d. Furthermore, the second RF generator 31b may generate a signal having a frequency of, for example, 13 MHz as a bias RF signal and supply the signal to the lower electrode of the substrate support 11. Alternatively, the first DC generator 32a may supply a first DC signal to the lower electrode of the substrate support 11.

As paths through which a current based on the source RF signal supplied to the upper electrode 13d, that is, radio frequency power, flows, a first path that does not pass through plasma and a second path that passes through plasma are conceivable. In the first path, the current flows from the upper electrode 13d to the sidewall 10a through the shield 42, the second insulating portion 47, and the second support 43. In the second path, the current flows from the upper electrode 13d to the sidewall 10a through the plasma in the plasma processing space 10s. The second insulating portion 47 reduces the capacitance between the shield 42 and the second support 43 and increases the impedance of the first path. Therefore, the radio frequency power supplied to the upper electrode 13d is efficiently coupled to the plasma in the plasma processing space 10s. Also, the radio frequency power supplied to the upper electrode 13d is coupled to the plasma more efficiently also below the shield 42.

An inner wall 10t on the inner side of the sidewall 10a exposed to the plasma processing space 10s is composed of a conductor. The inner wall 10t includes silicon. The inner wall 10t may be formed from, for example, silicon. The inner wall 10t can serve as a counter electrode for the shield 42. At least a part of the current applied to the shield 42 flows to the sidewall 10a through the plasma in the plasma processing space 10s and the inner wall 10t. Thus, since the inner wall 10t is formed from a silicon-containing material, it is not necessary to separately dispose another member (device) serving as a counter electrode in the plasma processing space 10s.

As shown in FIG. 3, the plurality of annular members included in the ring assembly 112 include an edge ring ER and a cover ring CR. The edge ring ER is provided to improve the uniformity of etching. The edge ring ER of the present embodiment is composed of a material appropriately selected depending on the material of the film to be etched, and may be composed of, for example, a silicon-containing material. The edge ring ER may be included in the exposed portion of the substrate support 11.

The cover ring CR is an insulator, is supported on the upper surface of the ceramic member 1111a, and extends along the outer periphery of the edge ring ER. The cover ring CR has, for example, an annular shape so as to surround the periphery of the edge ring ER. The material of the cover ring CR is an insulating material and may be, for example, a ceramic such as quartz or alumina. The cover ring CR may be composed of a plurality of dielectric components. The cover ring CR may not be included in the exposed portion of the substrate support 11.

The gas supply 20 is configured to supply a carbon-containing gas into the plasma processing space 10s inside the plasma processing chamber 10 of the plasma processing apparatus 1. Hereinafter, the “carbon-containing gas” is also referred to as a precoat gas. For example, when generating plasma to form a film on the exposed portion, the gas supply 20 supplies the precoat gas.

The precoat gas is a gas containing at least one selected from the group consisting of a hydrocarbon gas, a hydrofluorocarbon gas, and a fluorocarbon gas. A hydrocarbon gas (CH-based gas) is a gas containing C and H, and is, for example, CH₄ gas, C₂H₆ gas, or the like. A fluorocarbon gas (CF-based gas) is a gas containing C and F, and is, for example, C₄F₈ gas, C₅F₈ gas, C₄F₆ gas, or the like. A hydrofluorocarbon gas (CHF-based gas) is a gas containing C, H, and F, and is, for example, CHF₃ gas, CH₂F₂ gas, or the like.

The precoat gas supplied from the gas supply 20 may further include an inert gas. The inert gas includes, for example, a noble gas such as Ar gas. The inert gas may include N₂ gas.

Furthermore, the gas supply 20 is configured to supply a cleaning gas for cleaning the portion exposed to the plasma processing space 10s. The gas supply 20 supplies the cleaning gas when, for example, the surface of the portion exposed to the plasma processing space 10s is cleaned. The cleaning gas described later includes, for example, sulfur hexafluoride (SF₆) gas and oxygen (O₂) gas.

Various embodiments of the plasma processing method in the present disclosure will now be described.

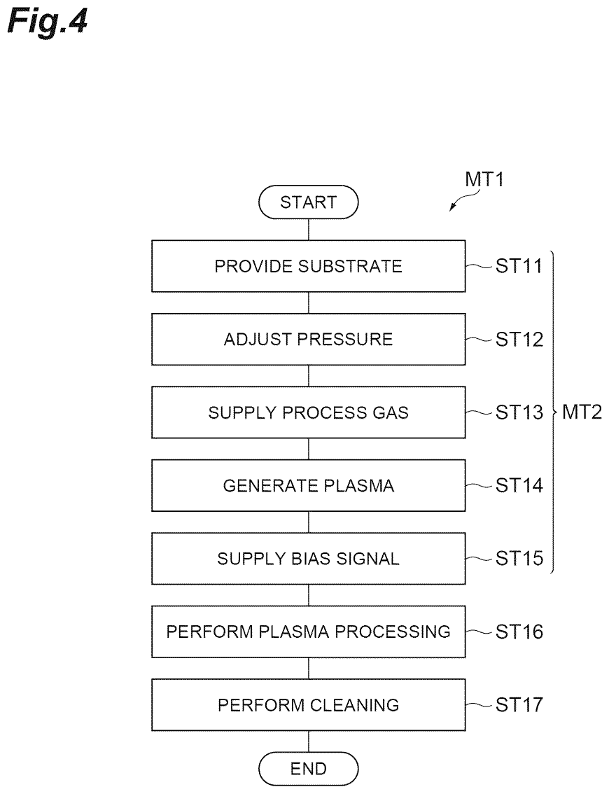

FIG. 4 is a flowchart showing a plasma processing method according to an embodiment (hereinafter also referred to as “method MT1”). As shown in FIG. 4, the method MT1 includes a film forming method MT2 (hereinafter also referred to as “method MT2”). The method MT2 includes a step ST11 of providing a substrate, a step ST12 of adjusting pressure, a step ST13 of supplying a precoat gas, a step ST14 of generating plasma, and a step ST15 of supplying a bias signal. The method MT2 may include a step ST16 of determining whether a predetermined condition is satisfied after step ST15. The method MT1 includes the method MT2, a step ST17 of performing plasma processing, and a step ST18 of performing cleaning.

In step ST11, the substrate W is carried into the plasma processing space 10s of the plasma processing apparatus 1 by a transport device and placed on the substrate support 11.

In the method MT1, step ST12 is then performed. In step ST12, the controller 2 controls the gas exhaust system 40 so as to adjust the pressure in the plasma processing space 10s to less than 50 mTorr. By controlling the gas exhaust system 40, gas is exhausted, and the pressure in the plasma processing space 10s is adjusted to less than 50 mTorr (less than 6.7 Pa). The gas exhaust system 40 may adjust the pressure in the plasma processing space 10s to less than 30 mTorr (less than approximately 4.0 Pa).

In the method MT1, step ST13 is then performed. In step ST13, the controller 2 controls the gas supply 20 so as to supply a carbon-containing gas into the plasma processing space 10s inside the plasma processing chamber 10 of the plasma processing apparatus 1. The precoat gas is supplied into the plasma processing space 10s through the showerhead 13 by the gas supply 20.

In the method MT1, step ST14 is performed during a period in which step ST13 is being performed. In step ST14, the controller 2 controls the first RF generator 31a so as to generate plasma from the precoat gas in the plasma processing space 10s during the supply of the precoat gas and to form films 61 to 63 on the portion (exposed portion) exposed to the plasma processing space 10s. In order to generate plasma in the plasma processing chamber 10 of the plasma processing apparatus 1, a source RF signal is generated in the first RF generator 31a, and the source RF signal is supplied to the upper electrode 13d. In step ST14, plasma is generated from the precoat gas supplied into the plasma processing space 10s in step ST13 by supplying radio frequency power based on the source RF signal.

In the method MT1, step ST15 is performed during a period in which step ST14 is being performed. In step ST15, during the period in which step ST14 is being performed, the controller 2 controls at least one of the second RF generator 31b or the first DC generator 32a or the second DC generator 32b so as to supply at least one bias signal to the exposed portion. In one embodiment, a bias RF signal may be generated in the second RF generator 31b, and the bias RF signal may be supplied as a bias signal to the lower electrode of the substrate support 11. The power level of the bias radio frequency signal supplied to the substrate support 11 in step ST15 may be 500 W or more. Alternatively, in step ST15, a first DC signal from the first DC generator 32a may be supplied as a bias signal to the lower electrode of the substrate support 11. By supplying the bias signal to the substrate support 11 in step ST15, ions are drawn from the plasma toward the substrate support 11.

Also, in step ST15, a second DC signal may be generated in the second DC generator 32b, and the second DC signal may be applied as a bias signal to the shield 42 through the DC connector 48. The absolute value of the voltage level of the second DC signal (DC voltage or voltage pulse) applied to the shield 42 in step ST15 may be 100 V or more. In step ST15, by applying the second DC signal, ions are drawn from the plasma toward the shield 42.

As described above, the bias signal is supplied in step ST15 while the state in which plasma is being generated from the precoat gas containing carbon in step ST14 continues. As a result, as shown in FIG. 3, a first film 61, a second film 62, and a third film 63 are formed on the exposed portion. The first film 61 is formed on the surface of at least one of the upper electrode 13d or the shield 42, which is the exposed portion in the ceiling 14. The second film 62 is formed on the surface of the inner wall 10t of the sidewall 10a. The third film 63 is formed on the surface of the edge ring ER.

In the method MT1, step ST16 is then performed. In step ST16, after execution of step ST14 and step ST15, the controller 2 controls each part of the plasma processing apparatus 1 so that plasma processing is performed on the substrate W in the plasma processing space 10s. For example, etching is performed on the substrate W in the plasma processing space 10s. After the plasma processing is performed, the substrate W is carried out from the substrate support 11 to outside the plasma processing space 10s by the transport device.

In the method MT1, step ST18 is then performed. In step ST18, after execution of step ST17, the controller 2 controls each part of the plasma processing apparatus 1 so as to clean the exposed portion. The gas supply 20 supplies a cleaning gas into the plasma processing space 10s. In order to generate plasma in the plasma processing chamber 10, a source RF signal is generated in the first RF generator 31a, and the source RF signal is supplied to the upper electrode 13d. By supplying radio frequency power based on the source RF signal, plasma is generated from the cleaning gas in the plasma processing space 10s supplied from the gas supply 20. The surface of the exposed portion in the plasma processing chamber 10 is cleaned by the plasma generated from the cleaning gas. After a predetermined time has elapsed, the gas supply 20 stops the supply of the cleaning gas. This completes the method MT1.

The first film 61, the second film 62, and the third film 63 formed in step ST14 and step ST15 of the method MT1 are conductive, hard, and high-density films. When a negative DC voltage having an absolute value of 100 V or more based on the second DC signal is applied to at least one of the upper electrode 13d or the shield 42, the conductive first film 61 is formed. By applying the DC voltage to at least one of the upper electrode 13d or the shield 42, compared to the case where the DC voltage is not applied to at least one of the upper electrode 13d or the shield 42, the resistance value decreases and the first film 61 that is harder and denser is formed. Also, in step ST15, by supplying a bias radio frequency signal having a power level of 500 W or more based on the bias RF signal to the lower electrode in a state where the DC voltage is applied, the first film 61 becomes a harder and denser film. Also, in step ST12, by adjusting the pressure in the plasma processing space 10s to less than 50 mTorr (less than 6.7 Pa), compared to the case where the pressure in the plasma processing space 10s is 50 mTorr or more, the first film 61 with a reduced resistance value is formed.

The second film 62 and the third film 63 are formed by supplying a bias radio frequency signal having a power level of 500 W or more based on the bias RF signal to the lower electrode, in addition to the application of the DC voltage based on the second DC signal as described above. By performing the application of the DC voltage and the supply of the bias radio frequency signal, compared to the case where the application of the DC voltage and the supply of the bias radio frequency signal are not performed, the resistance value decreases and the second film 62 and the third film 63 that are harder and denser are formed. Also, in step ST12, by adjusting the pressure in the plasma processing space 10s to less than 50 mTorr, compared to the case where the pressure in the plasma processing space 10s is 50 mTorr or more, the second film 62 and the third film 63 with reduced resistance values are formed. It should be noted that even when the pressure in the plasma processing space 10s is adjusted to 50 mTorr or more and less than 100 mTorr (less than 13.4 Pa), the third film 63 is formed, but it has been confirmed that the film deposition amount saturates at 50 mTorr.

The first film 61, the second film 62, and the third film 63 are amorphous films. That is, the crystal structure of carbon contained in the first film 61, the second film 62, and the third film 63 is constituted by a hybrid orbital d of sp3 orbitals and sp2 orbitals. The first film 61, the second film 62, and the third film 63 have higher hardness and density than graphite films and higher conductivity than diamond films.

When the first film 61 is not formed on at least one of the upper electrode 13d or the shield 42, there is no counter electrode for the DC voltage, and therefore the DC voltage may not be applied to the upper electrode 13d and the shield 42 (no current flows). Also, when the first film 61 is not formed on at least one of the upper electrode 13d or the shield 42, the DC voltage may become unstable, and arcing marks may be formed on the upper electrode 13d. Since the first film 61 is a conductive film, the DC voltage applied to at least one of the upper electrode 13d or the shield 42 is appropriately and stably applied, and it is possible to suppress the formation of arcing marks on the upper electrode 13d.

Also, the first film 61, the second film 62, and the third film 63 cover the surface of the upper electrode 13d and the surface of the shield 42, the surface of the inner wall 10t, and the surface of the edge ring ER, respectively, which are the exposed portions. By forming the first film 61, the second film 62, and the third film 63 as hard films, peeling of each film is suppressed, and it is possible to suppress reaction products from adhering as particles on the surface of each exposed portion.

In the plasma processing method MT1, the film forming method MT2, and the plasma processing apparatus 1 described above, plasma is generated in step ST14 in a state where the precoat gas is supplied in step ST13. In step ST15, by supplying at least one bias signal to the exposed portion, a conductive film can be formed on the exposed portion. This film can reduce the possibility of arcing marks being formed on the exposed portion covered by the film and suppress reaction products from adhering as particles. Therefore, the plasma processing method MT1, the film forming method MT2, and the plasma processing apparatus 1 can protect the portion (exposed portion) exposed to the plasma processing space 10s.

Also, the exposed portion includes at least one of the upper electrode 13d or the shield 42. When a DC voltage is applied to at least one of the upper electrode 13d or the shield 42 in step ST15, at least the first film 61 is formed on the upper electrode 13d and the shield 42. Also, when a DC voltage of 100 V or more is applied to at least one of the upper electrode 13d or the shield 42, the first film 61 with higher conductivity, greater hardness, and higher density is formed. By forming the first film 61, when plasma processing such as step ST17 is performed, the DC voltage applied to at least one of the upper electrode 13d or the shield 42 is stabilized, and the formation of arcing marks on the upper electrode 13d is suppressed. Also, by forming the hard first film 61, peeling of the first film 61 is suppressed, and it is possible to suppress reaction products from adhering as particles on the surface of the upper electrode 13d and the shield 42.

Also, the exposed portion includes the substrate support 11. When a bias radio frequency signal is supplied to the substrate support 11 in step ST15, the first film 61 is formed on the upper electrode 13d and the shield 42. Also, when a DC voltage is applied to at least one of the upper electrode 13d or the shield 42 in step ST15 together with the supply of the bias radio frequency signal, the second film 62 is formed on the inner wall 10t and the third film 63 is formed on the edge ring ER. Also, when radio frequency power of 500 W or more based on the bias radio frequency signal is supplied to the substrate support 11, the first film 61, the second film 62, and the third film 63 with higher conductivity, greater hardness, and higher density are formed. By forming the first film 61, when plasma processing such as step ST17 is performed, the DC voltage applied to at least one of the upper electrode 13d or the shield 42 is stabilized, and the formation of arcing marks on the upper electrode 13d is suppressed. Also, by forming the first film 61, the second film 62, and the third film 63, when plasma processing such as step ST17 is performed, it is possible to suppress reaction products from adhering as particles on the surface of each exposed portion.

Also, in a state where the pressure is high in step ST12, ions are more likely to collide with neutral particles, making it difficult to draw in ions. By creating a state in which ions that have maintained their energy without colliding with neutral particles are drawn in, it is possible to deposit a film at a higher density on the exposed portion. For this reason, by setting the pressure to less than 50 mTorr, it is possible to reduce the possibility of ions colliding with neutral particles and to create a state in which ions that have maintained their energy are drawn in. Therefore, by adjusting the pressure in the plasma processing space 10s to less than 50 mTorr (less than 6.7 Pa) based on the control of the controller 2 in step ST12, the first film 61, the second film 62, and the third film 63 that are conductive, hard, and high-density are formed. It should be noted that by adjusting the pressure in the plasma processing space 10s to less than 30 mTorr (less than 4.0 Pa) based on the control of the controller 2 in step ST12, it is possible to further suppress reaction products from adhering as particles on the exposed portion.

Also, in step ST13, the precoat gas supplied from the gas supply 20 includes a hydrocarbon gas, a hydrofluorocarbon gas, a fluorocarbon gas, or a combination thereof. Since the precoat gas is a carbon-containing gas, when plasma is generated from the precoat gas and a film is formed on the exposed portion in step ST14 and step ST15, the film has conductivity. As a result, the conductive first film 61 is formed, the DC voltage applied to at least one of the upper electrode 13d or the shield 42 is stabilized, and the formation of arcing marks on the upper electrode 13d is suppressed.

Also, since the precoat gas further includes an inert gas, the partial pressure of the carbon-containing gas and the partial pressure of the inert gas can be adjusted, so that sufficient pressure reduction can be achieved when adjusting the pressure in the plasma processing space 10s in step ST12.

Also, the first film 61, the second film 62, and the third film 63 are amorphous films. Examples of carbon-containing structures include graphite and diamond. Graphite has sp2 orbitals and is a conductor having conductivity, but has low hardness and density. On the other hand, diamond has sp3 orbitals and is an insulator (having no conductivity), but has high hardness and density. From the viewpoint of allowing power having a DC voltage to flow in a stable state and suppressing peeling of the film, a film having a structure that is conductive and has high hardness and density is required. Since the above-described first film 61, second film 62, and third film 63 are amorphous films, they have hybrid orbitals of sp3 orbitals and sp2 orbitals, and have a structure that is conductive and has high hardness and density. This allows power having a DC voltage to flow stably and suppresses the occurrence of peeling of the film.

Also, in step ST11, by placing the substrate W on the substrate support 11, it is possible to suppress the influence of plasma and particles on the substrate support 11. It should be noted that step ST11 may not be performed.

Also, the plasma processing apparatus 1 may have a plurality of DC connectors 48. That is, the DC connector 48 may be connected to the upper electrode 13d so that the second DC signal is applied directly to the upper electrode 13d without going through the shield 42. In this case, the second DC signal may be applied to each of the upper electrode 13d and the shield 42.

Although various exemplary embodiments have been described above, various additions, omissions, substitutions, and changes may be made without being limited to the exemplary embodiments described above. Also, it is possible to combine elements in different embodiments to form other embodiments. For example, in step ST15, a bias RF signal may not be generated in the second RF generator 31b, and radio frequency power based on the bias RF signal may not be supplied to the lower electrode. Even in this case, at least the first film 61 is formed on the exposed portion in the ceiling 14. For example, the upper electrode 13d may be electrically connected to the second DC generator 32b. Even in this case, at least the first film 61 is formed on the exposed portion in the ceiling 14.

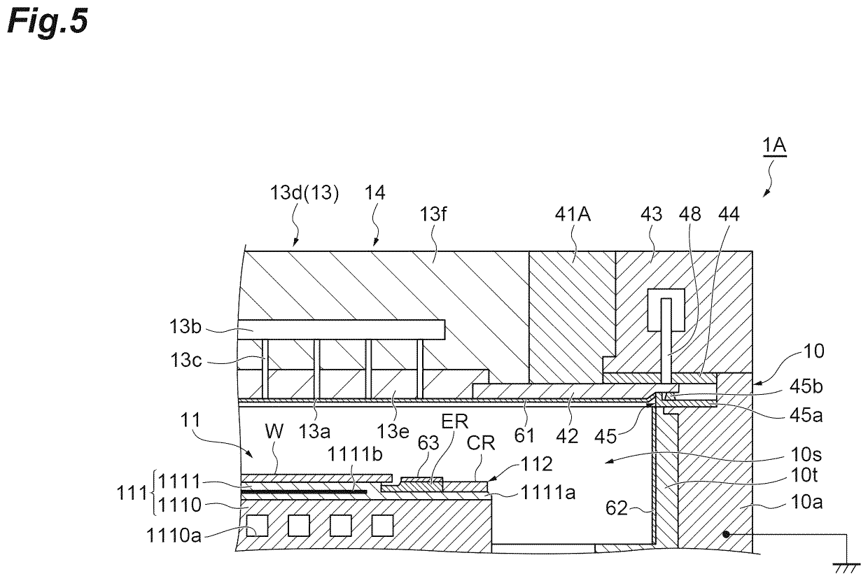

The plasma processing apparatus according to another exemplary embodiment used in the plasma processing apparatus will now be described with reference to FIG. 5. FIG. 5 is a diagram for explaining a plasma processing apparatus according to another exemplary embodiment. A plasma processing apparatus 1A according to the exemplary embodiment shown in FIG. 5 differs from the plasma processing apparatus 1 in that it includes a first insulator 41A and a third insulator 44. That is, the plasma processing apparatus 1A differs from the plasma processing apparatus 1 in that the plasma processing apparatus 1A includes a third insulator 44. The first insulator 41A is an example of an insulating portion.

The first insulator 41A is a member corresponding to the first insulating portion 46 of the plasma processing apparatus 1. The first insulator 41A is provided between the upper electrode 13d and the plasma processing chamber 10. The first insulator 41A electrically isolates the upper electrode 13d from the plasma processing chamber 10. The first insulator 41A is provided on the outer side of the upper electrode 13d (on the sidewall 10a side). The first insulator 41A has a substantially annular shape and extends in the circumferential direction so as to surround the upper electrode 13d. The first insulator 41A is formed from an insulator such as quartz.

The plasma processing apparatus 1A further includes at least one third insulator 44. The third insulator 44 is a member corresponding to the second insulating portion 47 of the plasma processing apparatus 1. The at least one third insulator 44 is provided on the outer side of the first insulator 41A and on the shield 42. The at least one third insulator 44 is interposed between the plasma processing chamber 10 and the shield 42. In the example shown in FIG. 5, the at least one third insulator 44 is provided such that its lower surface is in contact with the upper surface of the outer portion of the shield 42. The at least one third insulator 44 is provided between the shield 42 and the second support 43. The at least one third insulator 44 is, for example, a substantially annular plate-shaped member. The at least one third insulator 44 is formed from an insulator such as an insulating ceramic, quartz, or a metal oxide.

Even when the plasma processing method MT1 and the film forming method MT2 are performed in the plasma processing apparatus 1A, the same advantageous effects as those obtained when the plasma processing method MT1 and the film forming method MT2 are performed in the plasma processing apparatus 1 described above are achieved.

Here, various exemplary embodiments included in the present disclosure are described in E1 to E35 below.
E1 A film forming method using a plasma processing apparatus, the plasma processing apparatus including:
   a chamber that is electrically grounded and provides a plasma processing space;
   a substrate support in the chamber and configured to support a substrate;
   an upper electrode that is a part of a ceiling configured to close an opening of the chamber above the plasma processing space, the upper electrode being configured to apply radio frequency power for generating a plasma and being above the substrate support;
   a first insulator that is a part of the ceiling and is between the upper electrode and the chamber to electrically isolate the upper electrode from the chamber; and
   a shield that is another part of the ceiling, has conductivity, is formed from a silicon-containing material, and extends from a peripheral edge of the upper electrode to the chamber, and
   the film forming method comprising:
   supplying a carbon-containing gas into a plasma processing space inside the chamber;
   generating plasma from the gas in the plasma processing space to form a film on a portion exposed to the plasma processing space during execution of the supplying a carbon-containing gas, at least a part of the portion including a conductor; and
   supplying at least one bias signal to the portion during a period in which the generating plasma is being performed.
E2 The film forming method according to E1, wherein
   the portion includes at least one of the upper electrode or the shield, and
   in the supplying at least one bias signal, a DC voltage is applied as the at least one bias signal to at least one of the upper electrode or the shield.
E3 The film forming method according to E2, wherein
   in the supplying at least one bias signal, a negative DC voltage having an absolute value of 100 V or more is applied as the at least one bias signal to at least one of the upper electrode or the shield.
E4 The film forming method according to any one of E1 to E3, wherein
   the portion includes the substrate support, and
   in the supplying at least one bias signal, a bias radio frequency signal is supplied to the substrate support as the at least one bias signal.
E5 The film forming method according to E4, wherein
   in the supplying at least one bias signal, the bias radio frequency signal having a power level of 500 W or more is supplied to the substrate support.
E6 The film forming method according to any one of E1 to E5, further comprising:
   adjusting a pressure in the plasma processing space to less than 6.7 Pa during the supplying at least one bias signal.
E7 The film forming method according to any one of E1 to E6, wherein
   the gas includes at least one selected from the group consisting of a hydrocarbon gas, a hydrofluorocarbon gas, and a fluorocarbon gas.
E8 The film forming method according to any one of E1 to E7, wherein
   the gas further includes an inert gas.
E9 The film forming method according to E8, wherein
   the inert gas includes a noble gas.
E10 The film forming method according to any one of E1 to E9, wherein
   the film is an amorphous film.
E11 The film forming method according to any one of E1 to E10, wherein
   the plasma processing apparatus further comprises:
   at least one second insulator on an outer side of the first insulator and on the shield and interposed between the chamber and the shield; and
   at least one third insulator is below the shield and interposed between the chamber and the shield, such that the at least one third insulator supports the shield between the at least one second insulator and the at least one third insulator.
E12 The film forming method according to any one of E1 to E11, wherein
   the portion includes at least an inner wall on an inner side of a sidewall of the chamber, and the at least inner wall includes a conductor.
E13 A plasma processing method using a plasma processing apparatus, the plasma processing apparatus comprising:
   a chamber that is electrically grounded and provides a plasma processing space;
   a substrate support in the chamber and configured to support a substrate;
   an upper electrode that is a part of a ceiling configured to close an opening of the chamber above the plasma processing space, the upper electrode being configured to apply radio frequency power for generating the plasma and being above the substrate support;
   an insulating portion that is a part of the ceiling and is between the upper electrode and the chamber to electrically isolate the upper electrode from the chamber; and
   a shield that is another part of the ceiling, has conductivity, is formed from a silicon-containing material, and extends from a peripheral edge of the upper electrode to the chamber, and
   the plasma processing method comprising:
   supplying a carbon-containing gas into a plasma processing space inside the chamber;
   generating plasma from the gas in the plasma processing space to form a film on a portion exposed to the plasma processing space during execution of the supplying a carbon-containing gas, at least a part of the portion is including a conductor;
   supplying at least one bias signal to the portion during a period in which the generating plasma is being performed;
   performing plasma processing on a substrate in the plasma processing space after execution of the generating plasma and the supplying at least one bias signal; and
   cleaning the portion after execution of the performing plasma processing.
E14 The plasma processing method according to E13, wherein
   the portion includes at least one of the upper electrode or the shield, and
   in the supplying at least one bias signal, a DC voltage is applied as the at least one bias signal to at least one of the upper electrode or the shield.
E15 The plasma processing method according to E14, wherein
   in the supplying at least one bias signal, a negative DC voltage having an absolute value of 100 V or more is applied as the at least one bias signal to at least one of the upper electrode or the shield.
E16 The plasma processing method according to any one of E12 to E15, wherein
   the portion includes the substrate support, and
   in the supplying at least one bias signal, a bias radio frequency signal is supplied to the substrate support as the at least one bias signal.
E17 The plasma processing method according to E16, wherein
   in the supplying at least one bias signal, the bias radio frequency signal having a power level of 500 W or more is supplied to the substrate support.
E18 The plasma processing method according to any one of E13 to E17, wherein
   in the cleaning, the film formed on the portion is at least partially removed.
E19 The plasma processing method according to any one of E13 to E18, wherein
   in the cleaning, a cleaning gas including a halogen-containing gas is supplied and plasma is generated from the cleaning gas.
E20 The plasma processing method according to any one of E13 to E19, further comprising:
   adjusting the pressure in the plasma processing space to less than 6.7 Pa in the supplying at least one bias signal.
E21 The plasma processing method according to any one of E13 to E20, wherein
   the gas includes at least one selected from the group consisting of a hydrocarbon gas, a hydrofluorocarbon gas, and a fluorocarbon gas.
E22 The plasma processing method according to any one of E13 to E21, wherein
   the gas further includes an inert gas.
E23 The plasma processing method according to E22, wherein
   the inert gas includes a noble gas.
E24 The plasma processing method according to any one of E11 to E23, wherein
   the film is an amorphous film.
E25 The plasma processing method according to any one of E1 to E24, wherein the plasma processing apparatus further comprises:
   at least one second insulator on the outer side of the first insulator and on the shield so as to be interposed between the chamber and the shield; and
   at least one third insulator is below the shield and interposed between the chamber and the shield, such that the at least one third insulator supports the shield between the at least one second insulator and the at least one third insulator.
E26 The plasma processing method according to any one of E1 to E25, wherein
   the portion includes at least an inner wall on an inner side of a sidewall of the chamber and the at least inner wall is composed of a conductor.
E27 A plasma processing apparatus, comprising:
   a chamber that is electrically grounded and provides a plasma processing space;
   a gas supply configured to supply a gas into the chamber;
   a substrate support in the chamber and configured to support a substrate;
   an upper electrode that is a part of a ceiling configured to close an opening of the chamber above the plasma processing space, the upper electrode being configured to apply radio frequency power and being above the substrate support;
   an insulating portion that is a part of the ceiling and is between the upper electrode and the chamber to electrically isolate the upper electrode from the chamber;
   a shield that is another part of the ceiling, has conductivity, is formed from a silicon-containing material, and extends from a peripheral edge of the upper electrode to the chamber;
   a plasma generator configured to generate plasma from a gas;
   at least one bias generator configured to supply at least one bias signal to a portion exposed to the plasma processing space, the portion including a conductor; and
   a controller configured to control the gas supply, the plasma generator, and the at least one bias generator to execute:
   supplying a carbon-containing gas from the gas supply into the plasma processing space;
   generating plasma from the gas in the plasma processing space using the plasma generator and forming a film on the portion during execution of the supplying a carbon-containing gas;
   supplying the at least one bias signal from the at least one bias generator to the portion during a period in which the generating plasma is being performed;
   performing plasma processing on a substrate in the plasma processing space after execution of the generating plasma; and
   cleaning the portion after execution of the performing plasma processing.
E28 The plasma processing apparatus according to E27, wherein
   the controller controls to at least partially remove the film formed on the portion in the cleaning.
E29 The plasma processing apparatus according to E27 or E28, wherein
   the controller controls to supply a cleaning gas including a halogen-containing gas and generate plasma from the cleaning gas in the cleaning.
E30 A plasma processing apparatus, comprising:
   a chamber that is electrically grounded and provides a plasma processing space;
   a gas supply configured to supply a gas into the chamber;
   a substrate support in the chamber and configured to support a substrate;
   an upper electrode that is a part of a ceiling configured to close an opening of the chamber above the plasma processing space, the upper electrode being configured to be capable of applying radio frequency power, and being above the substrate support;
   a first insulator that is a part of the ceiling and is between the upper electrode and the chamber to electrically isolate the upper electrode from the chamber;
   a shield that is another part of the ceiling, has conductivity, is formed from a silicon-containing material, and extends from a peripheral edge of the upper electrode to the chamber;
   a plasma generator configured to generate plasma from a gas;
   at least one bias generator configured to supply at least one bias signal to a portion exposed to the plasma processing space, the portion being composed of a conductor; and
   a controller,
   wherein the controller controls the gas supply, the plasma generator, and the at least one bias generator to execute:
   supplying a carbon-containing gas from the gas supply into the plasma processing space;
   generating plasma from the gas in the plasma processing space using the plasma generator and forming a film on the portion during execution of the supplying a carbon-containing gas; and
   supplying the at least one bias signal from the at least one bias generator to the portion during a period in which the generating plasma is being performed.
E31 The plasma processing apparatus according to any one of E27 to E30, wherein
   the portion includes at least one of the upper electrode or the shield, and
   the controller is configured to control the at least one bias generator to apply a DC voltage as the at least one bias signal to at least one of the upper electrode or the shield as the at least one bias signal during the supplying the at least one bias signal.
E32 The plasma processing apparatus according to E31, wherein
   the controller is configured to control the at least one bias generator to apply a DC voltage of 100 V or more to as the at least one bias signal to at least one of the upper electrode or the shield as the at least one bias signal during the supplying the at least one bias signal.
E33 The plasma processing apparatus according to any one of E27 to E32, wherein
   the portion includes the substrate support, and
   the controller is configured to control the at least one bias generator to supply a bias radio frequency signal to the substrate support as the at least one bias signal during the supplying the at least one bias signal.
E34 The plasma processing apparatus according to E33, wherein
   the controller is configured to control to supply radio frequency power having a power level of 500 W or more based on the bias radio frequency signal to the substrate support as the at least one bias signal during the supplying the at least one bias signal.
E35 The plasma processing apparatus according to any one of E27 to E34, further comprising:
   adjusting the pressure in the plasma processing space to less than 6.7 Pa during the supplying the at least one bias signal.
E36 The plasma processing apparatus according to any one of E27 to E35, wherein
   the gas includes at least one selected from the group consisting of a hydrocarbon gas, a hydrofluorocarbon gas, and a fluorocarbon gas.
E37 The plasma processing apparatus according to any one of E27 to E36, wherein
   the gas further includes an inert gas.
E38 The plasma processing apparatus according to E37, wherein
   the inert gas includes a noble gas.
E39 The plasma processing apparatus according to any one of E27 to E38, wherein
   the film is an amorphous film.
E40 The plasma processing apparatus according to any one of E27 to E39, wherein the plasma processing apparatus further comprises:
   at least one second insulator on the outer side of the first insulator and on the shield to be interposed between the chamber and the shield; and
   at least one third insulator is below the shield and interposed between the chamber and the shield, such that the at least one third insulator supports the shield between the at least one second insulator and the at least one third insulator.
E41 The plasma processing apparatus according to any one of E27 to E40, wherein
   the portion includes at least an inner wall on an inner side of a sidewall of the chamber and the at least inner wall is composed of a conductor.

From the above description, it will be understood that various embodiments of the present disclosure are described herein for purposes of explanation, and that various changes may be made without departing from the scope and spirit of the present disclosure. Therefore, the various embodiments disclosed herein are not intended to be limiting, and the true scope and spirit are indicated by the appended claims.

What is claimed is:

1. A film forming method using a plasma processing apparatus, the plasma processing apparatus including:
a chamber that is electrically grounded and provides a plasma processing space;
a substrate support in the chamber and configured to support a substrate;
an upper electrode that is a part of a ceiling configured to close an opening of the chamber above the plasma processing space, the upper electrode being configured to apply radio frequency power for generating a plasma and being above the substrate support;
a first insulator that is a part of the ceiling and is between the upper electrode and the chamber to electrically isolate the upper electrode from the chamber; and
a shield that is another part of the ceiling, has conductivity, includes a silicon-containing material, and extends from a peripheral edge of the upper electrode to the chamber, and
the film forming method comprising:
supplying a carbon-containing gas into a plasma processing space inside the chamber;
generating plasma from the gas in the plasma processing space to form a film on a portion exposed to the plasma processing space during execution of the supplying a carbon-containing gas, at least a part of the portion including a conductor; and
supplying at least one bias signal to the portion during a period in which the generating plasma is being performed.

2. The film forming method according to claim 1, wherein
the portion includes at least one of the upper electrode or the shield, and
in the supplying at least one bias signal, a DC voltage is applied as the at least one bias signal to at least one of the upper electrode or the shield.

3. The film forming method according to claim 2, wherein
in the supplying at least one bias signal, a negative DC voltage having an absolute value of 100 V or more is applied as the at least one bias signal to at least one of the upper electrode or the shield.

4. The film forming method according to claim 1, wherein
the portion includes the substrate support, and
in the supplying at least one bias signal, a bias radio frequency signal is supplied to the substrate support as the at least one bias signal.

5. The film forming method according to claim 4, wherein
in the supplying at least one bias signal, the bias radio frequency signal having a power level of 500 W or more is supplied to the substrate support.

6. The film forming method according to claim 1, further comprising:
adjusting a pressure in the plasma processing space to less than 6.7 Pa during the supplying at least one bias signal.

7. The film forming method according to claim 1, wherein
the gas includes at least one selected from the group consisting of a hydrocarbon gas, a hydrofluorocarbon gas, and a fluorocarbon gas.

8. The film forming method according to claim 1, wherein
the gas further includes an inert gas.

9. The film forming method according to claim 8, wherein
the inert gas includes a noble gas.

10. The film forming method according to claim 1, wherein
the film is an amorphous film.

11. The film forming method according to claim 1, wherein
the plasma processing apparatus further comprises:
at least one second insulator on an outer side of the first insulator and on the shield and interposed between the chamber and the shield; and
at least one third insulator is below the shield and interposed between the chamber and the shield, such that the at least one third insulator supports the shield between the at least one second insulator and the at least one third insulator.

12. The film forming method according to claim 1, wherein
the portion includes at least an inner wall on an inner side of a sidewall of the chamber, and the at least inner wall includes a conductor.

13. A plasma processing method using a plasma processing apparatus, the plasma processing apparatus comprising:
a chamber that is electrically grounded and provides a plasma processing space;
a substrate support in the chamber and configured to support a substrate;
an upper electrode that is a part of a ceiling configured to close an opening of the chamber above the plasma processing space, the upper electrode being configured to apply radio frequency power for generating the plasma and being above the substrate support;
an insulating portion that is a part of the ceiling and is between the upper electrode and the chamber to electrically isolate the upper electrode from the chamber; and
a shield that is another part of the ceiling, has conductivity, includes a silicon-containing material, and extends from a peripheral edge of the upper electrode to the chamber, and
the plasma processing method comprising:
supplying a carbon-containing gas into a plasma processing space inside the chamber;
generating plasma from the gas in the plasma processing space to form a film on a portion exposed to the plasma processing space during execution of the supplying a carbon-containing gas, at least a part of the portion is including a conductor;
supplying at least one bias signal to the portion during a period in which the generating plasma is being performed;
performing plasma processing on a substrate in the plasma processing space after execution of the generating plasma and the supplying at least one bias signal; and
cleaning the portion after execution of the performing plasma processing.

14. The plasma processing method according to claim 13, wherein
the portion includes at least one of the upper electrode or the shield, and
in the supplying at least one bias signal, a DC voltage is applied as the at least one bias signal to at least one of the upper electrode or the shield.

15. The plasma processing method according to claim 13, wherein
the portion includes the substrate support, and
in the supplying at least one bias signal, a bias radio frequency signal is supplied to the substrate support as the at least one bias signal.

16. The plasma processing method according to claim 13, wherein
in the cleaning, the film formed on the portion is at least partially removed.

17. The plasma processing method according to claim 13, wherein
in the cleaning, a cleaning gas including a halogen-containing gas is supplied and plasma is generated from the cleaning gas.

18. A plasma processing apparatus, comprising:
a chamber that is electrically grounded and provides a plasma processing space;
a gas supply configured to supply a gas into the chamber;
a substrate support in the chamber and configured to support a substrate;
an upper electrode that is a part of a ceiling configured to close an opening of the chamber above the plasma processing space, the upper electrode being configured to apply radio frequency power and being above the substrate support;
an insulating portion that is a part of the ceiling and is between the upper electrode and the chamber to electrically isolate the upper electrode from the chamber;
a shield that is another part of the ceiling, has conductivity, includes a silicon-containing material, and extends from a peripheral edge of the upper electrode to the chamber;
a plasma generator configured to generate plasma from a gas;
at least one bias generator configured to supply at least one bias signal to a portion exposed to the plasma processing space, the portion including a conductor; and
a controller configured to control the gas supply, the plasma generator, and the at least one bias generator to execute:
supplying a carbon-containing gas from the gas supply into the plasma processing space;
generating plasma from the gas in the plasma processing space using the plasma generator and forming a film on the portion during execution of the supplying a carbon-containing gas;
supplying the at least one bias signal from the at least one bias generator to the portion during a period in which the generating plasma is being performed;
performing plasma processing on a substrate in the plasma processing space after execution of the generating plasma; and
cleaning the portion after execution of the performing plasma processing.

19. The plasma processing apparatus according to claim 18, wherein
the portion includes at least one of the upper electrode or the shield, and
the controller is configured to control the at least one bias generator to apply a DC voltage as the at least one bias signal to at least one of the upper electrode or the shield as the at least one bias signal during the supplying the at least one bias signal.

20. The plasma processing apparatus according to claim 18, wherein
the portion includes the substrate support, and
the controller is configured to control the at least one bias generator to supply a bias radio frequency signal to the substrate support as the at least one bias signal during the supplying the at least one bias signal.
